(19) United States
(12) Patent Application Publication
(10) Pub. No.: US 2015/0364291 A1
(43) Pub. Date: Dec. 17, 2015

(54) LITHOGRAPHY APPARATUS, AND METHOD OF MANUFACTURING ARTICLE

(71) Applicant: CANON KABUSHIKI KAISHA, Tokyo (JP)

(72) Inventors: Shigeki Ogawa, Utsunomiya-shi (JP); Hideki Ina, Tokyo (JP); Satoru Oishi, Utsunomiya-shi (JP)

(21) Appl. No.: 14/736,831

(22) Filed: Jun. 11, 2015

(30) Foreign Application Priority Data
Jun. 12, 2014 (JP) 2014-121842

(51) Int. Cl. H01J 37/20; H01J 37/244; H01J 37/317

(52) U.S. Cl. CPC H01J 37/20; H01J 37/3174; H01J 37/244; H01J 2237/31728; H01J 2237/20

(57) ABSTRACT

The present invention provides a lithography apparatus which forms a pattern by sequentially irradiating a first region and a second region on a substrate with a beam, the apparatus including a beam detector configured to detect the beam, and a processor configured to obtain position information of the second region by giving a weight to first position information of the second region based on an output from the beam detector before irradiation of the first region with the beam, and giving a weight to second position information of the second region based on an output from the beam detector after the irradiation.

### BACKGROUND OF THE INVENTION

1. Field of the Invention

The present invention relates to a lithography apparatus, and a method of manufacturing an article.

2. Description of the Related Art

As a lithography apparatus for manufacturing an article such as a semiconductor device, an apparatus which forms a pattern on a substrate by using a beam such as an electron beam or ion beam is known. This apparatus uses a stitching method which divides one shot region into a plurality of regions, forms patterns by irradiating the plurality of divided regions with a beam, and forms a pattern by connecting these patterns.

In the stitching method, if patterns in regions are shifted when they are connected, the line width precision (also referred to as CD (Critical Dimension) precision or the line width uniformity) may decrease. Also, if a shift occurs when drawing a pattern by overlaying it on another pattern (underlying pattern) already formed on a substrate, the overlay precision may decrease.

For example, Japanese Patent No. 4468752 has disclosed a technique which sets a region (multiple drawing region) where drawing regions overlap each other, and ensures the line width precision by controlling drawing based on the relationship between each region and a drawing pattern.

In a drawing apparatus, the position of a beam for irradiating a substrate temporally changes due to, for example, the influence of a change in temperature or magnetic field in the apparatus, so the beam position must be calibrated (also called corrected or compensated for). If the beam position is calibrated, however, the beam position having continuously changed discontinuously changes. Accordingly, a linear pattern becomes discontinuous if the beam position is calibrated while the pattern is drawn. This may decrease the line width uniformity (line width precision). On the other hand, if the beam position is not calibrated, the overlay precision may decrease due to the change with time (temporal change) of the beam position. Also, if calibration is frequently performed in order to increase both the line width uniformity and overlay precision, the number of substrates processed per unit time (the throughput) may decrease.

### SUMMARY OF THE INVENTION

The present invention provides, for example, a lithography apparatus advantageous in terms of overlay precision and line width precision.

According to one aspect of the present invention, there is provided a lithography apparatus which forms a pattern by sequentially irradiating a first region and a second region on a substrate with a beam, the apparatus including a beam detector configured to detect the beam, and a processor configured to obtain position information of the second region by giving a weight to first position information of the second region based on an output from the beam detector before irradiation of the first region with the beam, and giving a weight to second position information of the second region based on an output from the beam detector after the irradiation.

Further aspects of the present invention will become apparent from the following description of exemplary embodiments with reference to the attached drawings.

### BRIEF DESCRIPTION OF THE DRAWINGS

FIG. 1 is a schematic view showing the arrangement of a drawing apparatus according to an aspect of the present invention.

FIG. 2 is a view showing a change with time in position of an electron beam for irradiating a substrate.

FIG. 3 is a view showing the relationship between the overlay precision and line width precision.

FIG. 4 is a flowchart for explaining a drawing process in the drawing apparatus shown in FIG. 1.

### DESCRIPTION OF THE EMBODIMENTS

Preferred embodiments of the present invention will be described below with reference to the accompanying drawings. Note that the same reference numerals denote the same members throughout the drawings, and a repetitive description thereof will not be given.

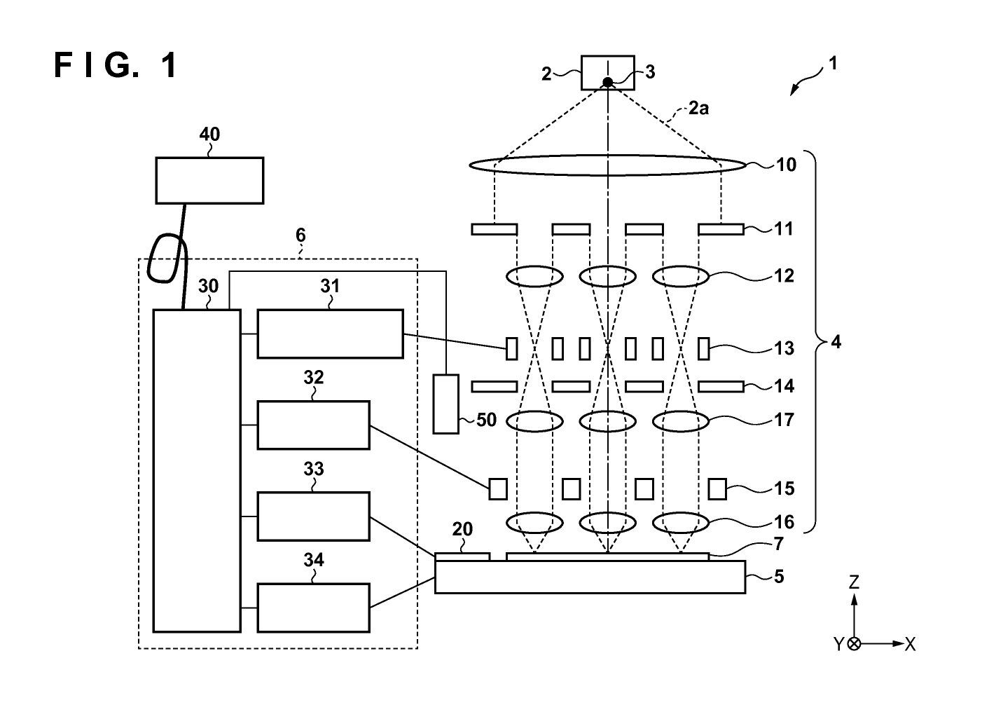

FIG. 1 is a schematic view showing the arrangement of a drawing apparatus 1 according to an aspect of the present invention. The drawing apparatus 1 is a lithography apparatus which forms a pattern on a substrate. The drawing apparatus 1 is a multi-beam drawing apparatus which draws a predetermined pattern on a predetermined position of a substrate by individually controlling ON/OFF of irradiation of a plurality of beams while deflecting the beams. Also, the drawing apparatus 1 adopts a stitching method which forms a pattern on a substrate on which regions to be drawn share an overlaying region (stitching region), by sequentially irradiating first and second regions on the substrate with a beam.

The beam is an electron beam in this embodiment, but may also be another charged particle beam such as an ion beam. Furthermore, the drawing apparatus 1 may also be a light beam drawing apparatus which performs drawing by diffracting (controlling) a light beam (laser beam) by using an acoustic optical element.

As shown in FIG. 1, the drawing apparatus 1 includes an electron gun 2, an optical system 4 which divides an electron beam emitted from a crossover 3 of the electron gun 2 into a plurality of electron beams, deflects the electron beams, and forms images of the electron beams, and a substrate stage 5 which holds a substrate 7. The drawing apparatus 1 also includes a controller 6 which controls the whole (that is, the operation of each constituent element) of the drawing apparatus 1, a detector 20, a setting unit (console) 40, and an alignment system 50. In the following explanation, the Z-axis is adopted as an electron beam irradiation direction with respect to a substrate, and the X-axis and Y-axis are adopted as directions perpendicular to each other in a plane perpendicular to the Z-axis.

Note that since an electron beam is abruptly attenuated in the atmosphere, and in order to prevent discharge by a high voltage, the constituent elements of the drawing apparatus 1 except for the controller 6 and setting unit 40 are arranged in a space in which the internal pressure is regulated by an evacuation system. For example, the electron gun 2 and optical system 4 are arranged in an electronic optical lens barrel kept (held) at a high vacuum degree, and the substrate stage 5 is arranged in a chamber kept at a vacuum degree lower than that in the electronic optical lens barrel. Also, the substrate 7 is, for example, a single-crystal silicon wafer, and the surface of the wafer is coated with a photosensitive resist.

The electron gun 2 emits an electron beam by the application of heat or an electric field. FIG. 1 shows (the trajectory of) an electron beam 2a emitted from the crossover 3 by the dotted lines. The optical system 4 includes, in the order named from the electron gun side, a collimator lens 10, aperture array 11, first electrostatic lens array 12, blanking deflector array 13, blanking aperture array 14, deflector array 15, and second electrostatic lens array 16. The optical system 4 may also include a third electrostatic lens array 17 on the downstream side of the blanking aperture array 14.

The collimator lens 10 is formed by an electromagnetic lens, and almost collimates the electron beam emitted from the crossover 3. The aperture array 11 has a plurality of circular openings arranged in a matrix, and divides the electron beam from the collimator lens 10 into a plurality of electron beams. The first electrostatic lens array 12 includes three electrode plates each having a circular opening, and forms images of the electron beams with respect to the blanking aperture array 14.

The blanking deflector array 13 and blanking aperture array 14 are arranged in a matrix, and control the ON (non-blanking)/OFF (blanking) operation of irradiation of each electron beam. The deflector array (deflector) 15 deflects the image on the substrate 7 held on the substrate stage 5 in the X-axis direction. The second electrostatic lens array 16 forms images of the electron beams having passed through the blanking aperture array 14 on the substrate 7. The second electrostatic lens array 16 also forms an image of the crossover 3 on the detector 20 arranged on the substrate stage 5.

The substrate stage 5 has an arrangement capable of 6-axis driving, and moves the substrate 7 in at least two axial directions, that is, the X-axis direction and Y-axis direction while holding the substrate 7 by electrostatic attraction. The position of the substrate stage 5 is measured in real time by an interferometer (laser interferometer) or the like. The resolution of this interferometer (that is, the driving precision of the substrate stage 5) is, for example, about 0.1 nm.

The detector (beam detector) 20 for detecting the characteristic of the electron beam for irradiating the substrate 7 is arranged on the substrate stage 5. The output signal (electrical signal) from the detector 20 is used to detect (the change of) the characteristics of the electron beam. The characteristics of the electron beam include the position, shape, intensity (intensity distribution), and the like of the electron beam. Any arrangement well known in the art is applicable to the detector 20. For example, the electron beam characteristics as described above are detected by using a slit.

The controller 6 includes a main controller 30, lens controller (not shown), blanking controller 31, deflection controller 32, detection controller 33, and stage controller 34, in order to control the operation of each constituent element pertaining to the drawing process of the drawing apparatus 1. The main controller 30 comprehensively controls the lens controller, blanking controller 31, deflection controller 32, detection controller 33, and stage controller 34.

The lens controller controls the operations of the collimator lens 10, first electrostatic lens array 12, second electrostatic lens array 16, and third electrostatic lens array 17. The blanking controller 31 controls the operation of the blanking deflector array 13 based on a blanking signal generated by a drawing pattern generator, bitmap converter, and blanking command generator. More specifically, the drawing pattern generator generates a drawing pattern, and the bitmap converter converts the drawing pattern into bitmap data. The blanking command generator generates a blanking signal based on the bitmap data. The deflection controller 32 controls the operation of the deflector array 15 based on a deflection signal generated by a deflection signal generator.

The detection controller 33 determines the presence/absence of electron beam irradiation based on the output signal from the detector 20, and inputs the determination result to the main controller 30. The detection controller 33 also obtains the characteristics of the electron beam (the position, shape, and intensity of the electron beam) for irradiating the substrate 7, by cooperating with the stage controller 34 and deflection controller 32 via the main controller 30. More specifically, the detection controller 33 obtains the electron beam characteristics based on the output signal from the detector 20, position information of the substrate stage 5 from the stage controller 34, and the electron beam deflection amount (deflection width) from the deflection controller 32.

Based on a command from the main controller 30, the stage controller 34 obtains the target position of the substrate stage 5, and controls the movement of the substrate stage 5 so that the substrate stage 5 is positioned in the target position. The movement of the substrate stage 5 is controlled by using the position of the substrate stage 5 measured by an interferometer (that is, measurement data obtained by the interferometer).

While a pattern is drawn, the stage controller 34 continuously scans the substrate stage 5 (the substrate 7) in the Y-axis direction. In this case, the deflector array 15 deflects the electron beam for irradiating the substrate 7 in the X-axis direction, based on the position of the substrate stage 5 measured by the interferometer. Also, the blanking deflector array 13 performs ON/OFF of electron beam irradiation so as to obtain a target dose (target irradiation amount) on a substrate.

The alignment system 50 is a mark detector for detecting a mark on a substrate. The alignment system 50 is used in, for example, global alignment, zone alignment, and die-by-die alignment, and detects an alignment mark (overlay mark) formed in each of a plurality of regions on a substrate. This alignment mark is drawn on a scribe line on a substrate simultaneously with a pattern to be drawn in a real element region on the substrate. The alignment system 50 can also detect a part of a pattern drawn in a real element region as an alignment mark, instead of the alignment mark to be drawn on the scribe line.

As described previously, the main controller 30 has a function of comprehensively controlling the lens controller, blanking controller 31, deflection controller 32, detection controller 33, and stage controller 34, and controlling the whole (operation) of the drawing apparatus 1. In addition, as will be described later, when aligning the substrate 7, the main controller 30 functions as a processor for determining a reference position (drawing position) for pattern formation. In this case, the main controller 30 functions as a processor for weighting first position information of a second region on a substrate before a first region on the substrate is irradiated with a beam, and second position information of the second region on the substrate after the first region is irradiated with the beam, thereby obtaining position information of the second region. Note that the first position information and second position information are obtained based on the output from the detector 20. Note also that at least one of the first position information and second position information is obtained based on the output from the alignment system 50 as well.

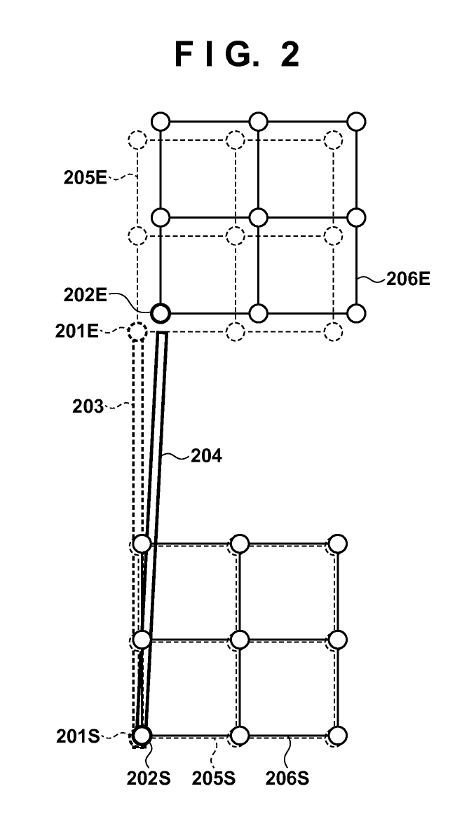

In the drawing apparatus 1 as shown in FIG. 2, the position of the electron beam for irradiating the substrate 7 temporally changes due to, for example, the influence of a change in temperature or magnetic field in the apparatus. FIG. 2 shows a position 201S of a first electron beam and a position 205S of a first grid when drawing is started, and a position 202S of a second electron beam and a position 206S of a second grid when drawing is started. The first electron beam and first grid draw a pattern (FIG. 203 indicated by the dotted lines, and the second electron beam and second grid draw a pattern (FIG. 204 indicated by the solid lines. FIG. 2 shows a state in which the position of the second electron beam temporally changes when the pattern 204 is drawn. 201E and 205E represent the positions of the first electron beam and first grid, respectively, when drawing is ended, and 202E and 206E represent the positions of the second electron beam and second grid, respectively, when drawing is ended. Accordingly, it is necessary to periodically detect the position of the electron beam by the detector 20, and calibrate the beam position.

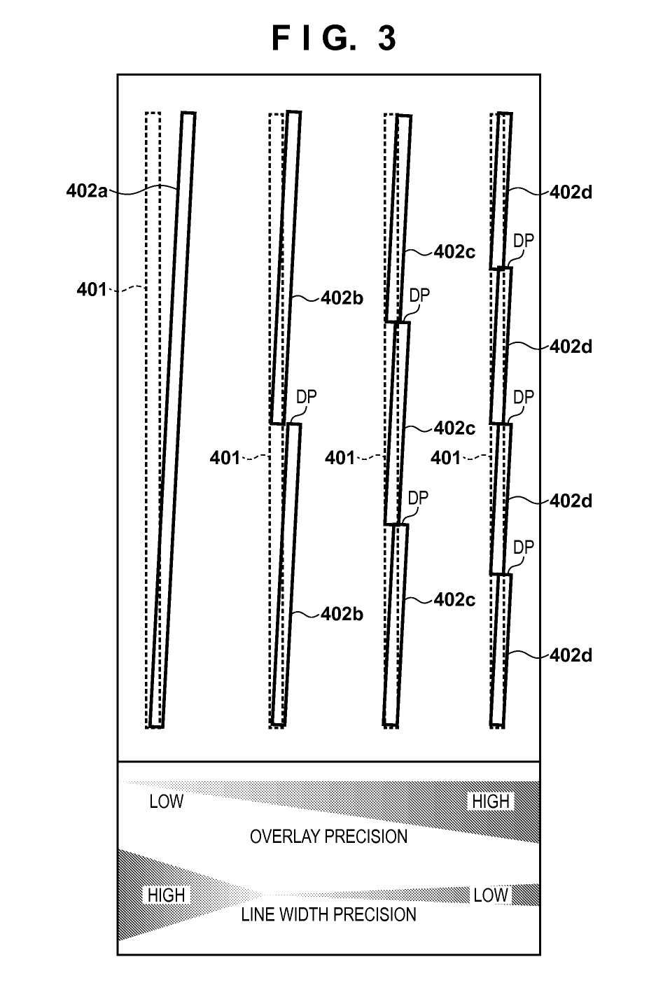

On the other hand, when the position of the electron beam is calibrated, the electron beam position having continuously changed discontinuously changes. Therefore, if the beam position is calibrated while a linear pattern is drawn, for example, the linear pattern becomes discontinuous as shown in FIG. 3. FIG. 3 shows an underlying pattern 401, and drawing patterns 402a, 402b, 402c, and 402d to be drawn as they are overlaid on the underlying pattern 401. To facilitate understanding, FIG. 3 extremely shows the change with time of the electron beam position. Referring to FIG. 3, when the position of the electron beam is not calibrated, an overlay shift occurs between the underlying pattern 401 and drawing pattern 402a. Also, the drawing patterns 402b, 402c, and 402d are drawn when the electron beam position is calibrated once, twice, and three times, respectively. As is apparent from FIG. 3, calibration of the electron beam position increases the overlay precision, but decreases the line width precision because a discontinuous point DP appears in the drawing pattern. On the other hand, when the electron beam position is not calibrated, the line width precision is kept, but the drawing pattern is drawn as it is shifted from the underlying pattern 401 due to the change with time of the electron beam position. Thus, calibration of the electron beam position exerts influence on both the overlay precision and line width precision. In other words, it is difficult to increase both the overlay precision and line width precision because they have a conflicting relationship.

Also, the overlay precision and line width precision required for pattern formation change in accordance with a semiconductor device or its manufacturing process. If the two precisions are individually corrected, therefore, the consequence may differ from a consequence wanted by the user (that is, the overlay precision and line width precision required for pattern formation may not be satisfied). In other words, line width correction may decrease the overlay precision, or overlay correction may decrease the line width precision.

In the drawing apparatus 1 of this embodiment, therefore, the user can freely input (control) whether to give priority to the overlay precision, give priority to the line width precision, or give equal priority to the overlay precision and line width precision. More specifically, the drawing apparatus 1 includes the setting unit 40 which sets the values of order parameters representing the priority of the overlay precision and line width precision, and the values of weight parameters representing weights to be given to overlay and line width, in accordance with user's input. The drawing apparatus 1 performs drawing in accordance with the values of the order parameters and weight parameters set by the setting unit 40, thereby ensuring the consequence wanted by the user, that is, the overlay precision and line width precision required for pattern formation.

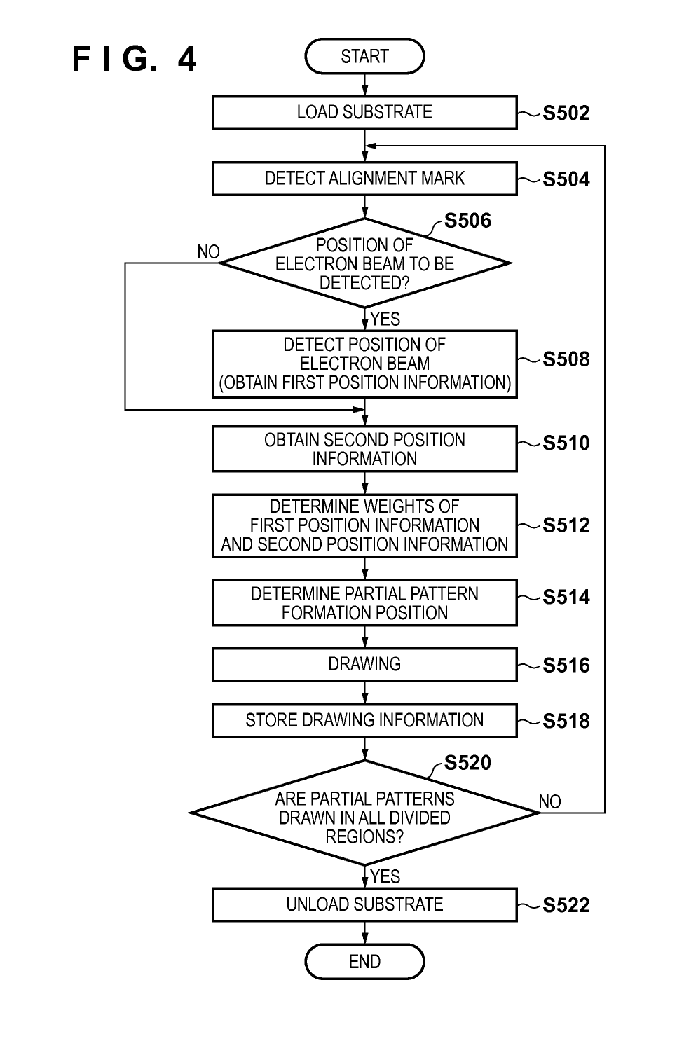

A drawing process performed using a stitching method in the drawing apparatus 1 will be explained with reference to FIG. 4. As described previously, this drawing process is performed by the controller 6, particularly, the main controller 30 by comprehensively controlling the individual units of the drawing apparatus 1. In this embodiment, assume that one shot region on a substrate is divided into a plurality of regions, and partial patterns are drawn in these divided regions.

In step S502, the substrate 7 is loaded into the drawing apparatus 1 from outside the drawing apparatus 1, and held on the substrate stage 5. The substrate 7 to be loaded into the drawing apparatus 1 is pre-coated with a resist necessary to draw a pattern. Also, an underlying pattern (circuit pattern) and an alignment mark are already formed on the substrate 7 to be loaded into the drawing apparatus 1.

In step S504, the alignment mark formed on the substrate 7 is detected based on the procedure of one of global alignment measurement, zone alignment measurement, and die-by-die alignment measurement. In the global alignment measurement, the alignment system 50 first detects the alignment mark formed in a global sample shot region (specific sample region) of a plurality of shot regions of the substrate 7. Then, processing (for example, a regression operation using a regression equation) is performed on the detection result of the alignment system 50, thereby obtaining the array (for example, the positions) of the shot regions on the substrate. In the zone alignment measurement, the alignment system 50 detects the alignment mark formed in a local shot region on the substrate, and the position of each shot region is obtained based on the detection result. The local shot region herein mentioned includes a target divided region as a target of partial pattern drawing, and a peripheral region of the target divided region, which is grouped with the target divided region. In the die-by-die alignment measurement, the alignment system 50 detects the alignment mark formed in the target divided region, and the position of each shot region is obtained based on the detection result.

In step S506, whether to detect the position of an electron beam for irradiating the substrate 7 is determined. A determination criterion in this step is, for example, a predetermined time interval, each substrate, or the drawing time (the cumulative irradiation time of the electron beam). A determination criterion like this is predetermined and set in the drawing apparatus 1 via the setting unit 40 or the like. When detecting the position of the electron beam for irradiating the substrate 7, the process advances to step S508. On the other hand, when not detecting the position of the electron beam for irradiating the substrate 7, the process advances to step S510.

In step S508, the detector 20 detects the position of the electron beam for irradiating the substrate 7. Also, based on the electron beam position detected by the detector 20, first position information (a drawing position) for forming a partial pattern is obtained for a target divided region (second region) of the plurality of divided regions on the substrate. The first position information is the position of the target divided region before a region (first region) adjacent to the target divided region on the substrate is irradiated with the beam, and is a drawing position where the line width precision is given priority.

In step S510, second position information (a drawing position) for forming a partial pattern is obtained for the target divided region. The second position information is the position of the target divided region after the region (first region) adjacent to the target divided region on the substrate is irradiated with the beam, and is a drawing region where the overlay precision is given priority. More specifically, the second position information is obtained based on the detection result of the alignment system 50 in step S504, and on the position of a partial pattern in a divided region where the partial pattern is already formed. Note that the position of a partial pattern in a divided region adjacent to the target divided region can be obtained by using, for example, drawing information when the partial pattern is drawn in the divided region adjacent to the target divided region. The drawing information is stored in, for example, a storage unit such as a memory of the controller 6, and contains, for example, the cumulative dose of the electron beam having irradiated the substrate 7 when the partial pattern is drawn, linear correction amounts such as a shift, magnification, and rotation during drawing, and the position of the substrate stage 5. The position of the partial pattern in the divided region adjacent to the target divided region may also be obtained based on the zone alignment measurement or die-by-die alignment measurement when the partial pattern is formed in the divided region adjacent to the target divided region. In other words, the position of the partial pattern in the divided region adjacent to the target divided region may also be obtained based on the alignment mark detected by the alignment system 50 when the partial pattern is formed in the adjacent divided region. Note that the position of the partial pattern in the divided region adjacent to the target divided region can be information about at least one of translation, rotation, shape, and dimension of the partial pattern.

In step S512, the value of the order parameter and the value of the weight parameter set by the setting unit 40 are obtained, and weights to be given to the first position information and second position information are determined in accordance with these values. The order parameter contains a variable representing whether to give priority to the overlay precision or line width precision. For example, when the variable of the order parameter is “1”, the line width precision is given priority, so the weight to be given to the first position information is “1”, and the weight to be given to the second position information is “0”. When the variable of the order parameter is “0”, the overlay precision is given priority, so the weight to be given to the first position information is “0”, and the weight to be given to the second position information is “1”. On the other hand, the weight parameter contains a first variable (first weight) representing the weight to be given to the first position information, and a second variable (second weight) representing the weight to be given to the second position information. Note that each of the first and second variables of the weight parameter is a real number of 0 (inclusive) to 1 (inclusive), and the sum of the first and second variables is 1. Therefore, the line width precision is given priority when the first variable is “1” and the second variable is “0”, and the overlay precision is given priority when the first variable is “0” and the second variable is “1”. In other cases, for example, when the first variable is “0.3” and the second variable is “0.7”, both the line width precision and overlay precision are taken into consideration at a ratio of 3:7.

In step S514, a partial pattern formation position is determined for the target divided region. More specifically, the weights determined in step S512 are given to the first position information obtained in step S508 and the second position information obtained in step S510, and the partial pattern formation position is determined based on the weighted first position information and second position information.

For example, let C_{A} be the weight of the line width precision (the value of the first variable), C_{B} be the weight of the overlay precision (the value of the second variable), (Sx, Sy) be the first position, and (Bx, By) be the second position. In this case, the formation position of the partial pattern is (C_{A}×Sx+C_{B}×Bx, C_{A}×Sy+C_{B}×By).

In step S516, the partial pattern is drawn in the target divided region based on the position determined in step S514. In step S518, drawing information (for example, the cumulative dose of the electron beam having irradiated the substrate 7, linear correction amounts such as a shift, magnification, and rotation during drawing, and the position of the substrate stage 5) when the partial pattern is drawn in the target divided region in step S516 is stored in, for example, a storage unit such as a memory of the controller 6. This drawing information stored in step S518 is used as needed when obtaining the first position (step S508).

In step S520, whether partial patterns are drawn in all divided regions on the substrate is determined. If partial patterns are drawn in not all divided regions on the substrate, a divided region where no partial pattern is drawn is set as a target divided region, and the process returns to step S504. If partial patterns are drawn in all divided regions on the substrate, the process advances to step S522, and the substrate 7 is unloaded outside the drawing apparatus 1.

In the drawing apparatus 1 as described above, the parameters for determining the priority between the overlay precision and line width precision can be set for each substrate or for each lot of substrates, although the present invention is not limited to this. Accordingly, the drawing apparatus 1 can implement a lithography apparatus advantageous in increasing both the overlay precision and line width precision required for pattern formation.

This embodiment has been explained by taking the case in which the drawing apparatus 1 is a multi-beam apparatus as an example. However, the same effect can be obtained even when the drawing apparatus 1 is a single-beam apparatus.

Also, when detecting the electron beam for irradiating the substrate 7 at a predetermined time interval, for example, the position of the electron beam cannot be obtained during the detection. In this case, it is also possible to estimate the position of the electron beam based on the position of the electron beam measured based on the output from the detector 20, and the elapsed time from this measurement. This estimation can be performed based on a fluctuation model whose validity is confirmed beforehand.

For example, when the main cause of the change with time of the electron beam position is heat generation in an electronic optical system, the position of the electron beam can be estimated based on the cumulative dose of the electron beam with respect to the substrate 7.

The drawing apparatus 1 is suitable for manufacturing an article, for example, a microdevice such as a semiconductor device, or an element having a microstructure. A method of manufacturing an article according to this embodiment includes a step of forming a latent-image pattern onto a resin dispensed on a substrate (a step of performing drawing on the substrate) by using the drawing apparatus 1, and a step of developing the substrate on which the latent-image pattern is formed by the above step (a step of developing the substrate having undergone drawing). This manufacturing method can further include other well-known steps (for example, oxidation, film formation, deposition, doping, planarization, etching, resist removal, dicing, bonding, and packaging). When compared to the conventional methods, the method of manufacturing an article according to this embodiment is advantageous in at least one of the performance, quality, productivity, and production cost of an article.

In the present invention, a lithography apparatus is not limited to a drawing apparatus and may also be applied to an exposure apparatus. The exposure apparatus is a lithography apparatus which exposes a substrate by using light or a beam such as a light beam or charged-particle beam via a reticle or mask and a projection optical system. Also, in the present invention, a plurality of divided regions on a substrate are applicable as a plurality of shot regions.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2014-121842 filed on Jun. 12, 2014, which is hereby incorporated by reference herein in its entirety.

What is claimed is:

1. A lithography apparatus which forms a pattern by sequentially irradiating a first region and a second region on a substrate with a beam, the apparatus comprising:
a beam detector configured to detect the beam; and
a processor configured to obtain position information of the second region by giving a weight to first position information of the second region based on an output from the beam detector before irradiation of the first region with the beam, and giving a weight to second position information of the second region based on an output from the beam detector after the irradiation.

2. The apparatus according to claim 1, further comprising a mark detector configured to detect a mark on the substrate,
wherein at least one of the first position information and the second position information is further based on an output from the mark detector.

3. The apparatus according to claim 1, further comprising a setting device configured to set the weight to be given to each of the first position information and the second position information in accordance with input thereto.

4. The apparatus according to claim 3, wherein the setting device configured to set a first weight to be given to the first position information and a second weight to be given to the second position information.

5. The apparatus according to claim 4, wherein each of the first weight and the second weight is a real number not smaller than 0 and not greater than 1, and a sum of the first weight and the second weight is 1.

6. The apparatus according to claim 2, wherein the processor is configured to obtain the first position information based on a procedure of one of global alignment, zone alignment and die-by-die alignment.

7. The apparatus according to claim 2, wherein the processor is configured to obtain the second position information based on a procedure of one of global alignment, zone alignment and die-by-die alignment.

8. The apparatus according to claim 1, wherein the processor is configured to estimate a position of the beam which irradiates at least one of the first region and the second region based on the output from the beam detector.

9. The apparatus according to claim 1, wherein the beam includes a charged-particle beam.

10. A method of manufacturing an article, the method comprising steps of:
forming a pattern on a substrate using a lithography apparatus; and
processing the substrate, on which the pattern has been formed, to manufacture the article, wherein the lithography apparatus forms the pattern by sequentially irradiating a first region and a second region on the substrate with a beam, and includes:
a beam detector configured to detect the beam; and
a processor configured to obtain position information of the second region by giving a weight to first position information of the second region based on an output from the beam detector before irradiation of the first region with the beam, and giving a weight to second position information of the second region based on an output from the beam detector after the irradiation.
